(19) United States
(12) Patent Application Publication
(10) Pub. No.: US 2025/0349366 A1
(43) Pub. Date: Nov. 13, 2025

(54) MANAGING ERASE OPERATIONS IN MEMORY SYSTEMS

(71) Applicant: Yangtze Memory Technologies Co., Ltd., Wuhan (CN)

(72) Inventors: Die HU, Wuhan (CN); Junyao ZHU, Wuhan (CN); Jing WEI, Wuhan (CN)

(21) Appl. No.: 18/777,874

(22) Filed: Jul. 19, 2024

(30) Foreign Application Priority Data
May 8, 2024 (CN) 202410571247.2

(51) Int. Cl. G11C 16/16; G11C 16/10; G11C 16/32

(52) U.S. Cl. CPC G11C 16/16; G11C 16/102; G11C 16/32

(57) ABSTRACT

Methods, systems, and apparatus for performing an erase operation in a memory system are described. An example system includes a memory device and a memory controller. The memory device includes a memory cell array and a peripheral circuit coupled to the memory cell array. Before applying an erase pulse to a source line coupled to the memory cell array, the peripheral circuit separately performs pre-programming operations on word lines and select gate lines of the memory cell array by performing a first pre-programing operation on word lines in a first time period and performing a second pre-programing operation on a first select gate line in a second time period.

### CROSS-REFERENCE TO RELATED APPLICATIONS

This application claims priority to Chinese Patent Application No. 202410571247.2, filed on May 8, 2024, which is hereby incorporated by reference in its entirety.

### TECHNICAL FIELD

The present disclosure generally relates to memory systems, and more specifically, to management of erase operations of memory systems.

### BACKGROUND

Erase operations in memory devices, particularly flash memory, present several challenges, including the wear and tear on memory cells, which can limit their lifespan due to a finite number of erase cycles. Storage inefficiencies associated with the erase operations may be addressed to maintain data integrity and device performance.

### SUMMARY

The present disclosure describes management of erase operations in memory systems.

In one aspect, the present disclosure describes a method performed by a peripheral circuit in a memory device. The method includes: before applying an erase pulse to a source line coupled to a memory cell array of the memory device, separately performing pre-programming operations on word lines and select gate lines of the memory cell array; and applying the erase pulse to the source line. The select gate lines include a first select gate line, and separately performing the pre-programming operations on the word lines and the select gate lines includes: performing a first pre-programing operation on the word lines in a first time period, and performing a second pre-programing operation on the first select gate line in a second time period different from the first time period.

In another aspect, the present disclosure describes a memory device. The memory device includes a memory cell array and a peripheral circuit coupled to the memory cell array. The peripheral circuit is configured to: before applying an erase pulse to a source line coupled to a memory cell array of the memory device, separately perform pre-programming operations on word lines and select gate lines of the memory cell array; and apply the erase pulse to the source line. The select gate lines include a first select gate line, and separately performing the pre-programming operations on the word lines and the select gate lines includes: performing a first pre-programing operation on the word lines in a first time period, and performing a second pre-programing operation on the first select gate line in a second time period different from the first time period.

In still another aspect, the present disclosure describes a system that includes a memory device and a controller coupled to the memory device. The memory device includes a memory cell array and a peripheral circuit coupled to the memory cell array. The peripheral circuit is configured to: before applying an erase pulse to a source line coupled to a memory cell array of the memory device, separately perform pre-programming operations on word lines and select gate lines of the memory cell array; and apply the erase pulse to the source line. The select gate lines include a first select gate line, and separately performing the pre-programming operations on the word lines and the select gate lines includes: performing a first pre-programing operation on the word lines in a first time period, and performing a second pre-programing operation on the first select gate line in a second time period different from the first time period.

The details of one or more implementations of the subject matter of this disclosure are set forth in the accompanying drawings and the description below. Other features, aspects, and advantages of the subject matter will become apparent from the description, the drawings, and the claims.

### BRIEF DESCRIPTION OF THE DRAWINGS

FIG. 1 illustrates a block diagram of an example system, in accordance with one or more implementations of the present disclosure.

FIG. 2A illustrates a diagram of an example memory card, in accordance with one or more implementations of the present disclosure.

FIG. 2B illustrates a diagram of an example solid-state drive (SSD), in accordance with one or more implementations of the present disclosure.

FIG. 3 illustrates a schematic circuit diagram of an example memory device, in accordance with one or more implementations of the present disclosure.

FIG. 4 illustrates a side view of a cross-section of an example memory cell array, in accordance with one or more implementations of the present disclosure.

FIG. 5 illustrates a block diagram of an example memory device, in accordance with one or more implementations of the present disclosure.

FIG. 6 illustrates threshold voltage distributions of memory cells in an example program operation, in accordance with one or more implementations of the present disclosure.

FIGS. 7A and 7B illustrate a waveform of word line voltages applied to a selected word line in an example program operation, in accordance with one or more implementations of the present disclosure.

FIG. 8 illustrates a flow chart of an example process of managing erase operations by a memory device, in accordance with one or more implementations of the present disclosure.

FIG. 9 illustrates a diagram of an example process of performing pre-programming operations, in accordance with one or more implementations of the present disclosure.

FIG. 10 illustrates an example of applying an erase pulse to a block of memory cells in a memory cell array, in accordance with one or more implementations of the present disclosure.

FIG. 11 illustrates a diagram of an example process of applying different voltage pulses to a source line, a select gate, and a word line coupled to a memory cell array, in accordance with one or more implementations of the present disclosure.

Like reference numbers and designations in the various drawings indicate like elements.

### DETAILED DESCRIPTION

The erase operation in memory devices is a process used to reset the data in memory cells back to a default state, typically making them ready for new data to be written. This operation is essential in flash memory technologies, such as NAND and NOR, where it involves applying specific electrical signals to remove the stored charge from the memory cells, thereby erasing the stored information. In memory devices, especially in the context of flash memory, there are several types of erase operations, each with its own mechanism and characteristics. These types of erase operations include Fowler-Nordheim (FN) tunneling erase, channel hot electron (CHE) injection erase, source side injection (SSI), thermal erase, gate-induced drain leakage (GIDL) erase, etc. Each of these methods has its own set of advantages, limitations, and suitability depending on the specific requirements of the memory device, such as speed, durability, power consumption, and the need for localized or block-level erasure. GIDL erase, for instance, is known for its lower power consumption and potential for finer granularity, but it must be carefully managed to balance performance, longevity, and reliability of the memory device.

GIDL in semiconductor manufacturing is a phenomenon that occurs in transistors of memory devices, such as metal-oxide-semiconductor field-effect transistors (MOSFETs). It is especially relevant in modern, scaled-down transistors where the dimensions are extremely small. GIDL happens when a high electric field is present at the drain junction in off-state conditions (when the transistor is supposed to be off). This high field is induced by the gate voltage. In certain conditions, especially when the transistor is miniaturized, this field can become strong enough to cause a significant amount of current to flow from the drain to the substrate, even though the transistor is off. This current flow is undesirable as it leads to power dissipation and affects the overall performance of the semiconductor device.

The primary factors that contribute to GIDL include thin oxide layers, high drain voltage, and material properties. GIDL can lead to increased static power consumption, which is a significant issue for battery-powered devices like smartphones and laptops. It can also affect the reliability and lifespan of the semiconductor device.

GIDL erase is a technique used in certain types of non-volatile memory, such as Flash memory, to improve performance by erasing data more efficiently. This technique leverages the GIDL effect, which is typically considered a parasitic effect in transistor operation, to advantageously erase data from memory cells.

In GIDL erase, a strong electric field is intentionally created across the thin gate oxide of a memory transistor, similar to the conditions that cause GIDL in regular transistors. This field causes electrons to tunnel from the floating gate of the transistor through the gate oxide to the substrate, effectively removing the stored charge from the floating gate. Since the charge state of the floating gate determines the data stored in the memory cell, this process effectively erases the data.

GIDL erase can be more energy-efficient compared to conventional erase methods, as it may require lower voltages and currents. It can potentially offer faster erase times, which can improve the overall performance of the memory device. As semiconductor devices scale down, conventional erase mechanisms face challenges due to the physical limitations of the materials and structures used. GIDL erase provides an alternative mechanism that can be more easily scaled with advanced manufacturing technologies.

Although the GIDL erase method offers potential benefits in terms of power efficiency, erase speed, and scalability, it also presents challenges in terms of control and long-term reliability of the memory cells.

For example, GIDL erase can cause voltage shifts or variations on select gates due to the inherent variability in tunneling rates and physical differences among individual memory cells. This can lead to non-uniform erasing and impact the performance and reliability of the memory device. The GIDL effect relies on quantum tunneling, a process that can be influenced by subtle variations in the physical structure of the transistor, such as differences in oxide thickness, doping concentrations, and surface roughness. These variations can lead to different tunneling rates for different cells, even under the same erase conditions. The variability in tunneling rates can result in a non-uniform erase across the memory array. Some cells might lose their charge faster than others, leading to a variation in the threshold voltages of the cells after the erase.

For example, excessive charge removal can occur, leading to an over-erased state of a memory cell. This over-erasing can shift a threshold voltage of the memory cell into a range that is not ideal for normal operation. Conversely, if the GIDL effect is not strong enough or is inconsistent, some cells may not be fully erased, leading to variations in the threshold voltages.

In some implementations, adding a pre-programming operation before the erase operation can help compensate for the voltage shift caused by GIDL erase. This technique helps to normalize the starting condition of memory cells before erasing, leading to a more uniform erase process of the memory cells.

In some cases, transistors in different sections of a memory array can experience different levels of threshold voltage shifts. For example, a memory array can include memory cells coupled by word lines and select gate transistors (also referred to as select gates) coupled by select gate lines. The select gate transistors can further include multiple layers or be arranged in different planes. The memory cells and select gate transistors can experience voltage shifts in different directions and/or at different levels. Such variations in the voltage shift can be attributed by several factors, such as a physical layout and structure, differing operational roles, exposure to erase and write cycles, material and manufacturing variabilities, electrical interference and crosstalk, and thermal effects. Therefore, a pre-programming process with joint control of word lines and select gate lines presents challenges in achieving precise voltage threshold control due to different adjustment requirements of word lines and select gates during pre-programming. Additionally, the varying word line loadings exert differential impacts on the select gates, further complicating the control of voltage thresholds. To compensate for the varying levels of voltage shifts experienced by different sections of a memory array in an erase operation, a non-uniform or tailored pre-programming scheme can be used that decouple or perform different or separate pre-programming operations on the different sections of a memory array. For example, and as described below in greater detail, different pre-programming operations can be performed on different sections of the memory array during different time periods. Therefore, instead of a conventional, uniform pre-programming approach, such as the application of same pre-programming operations to both word lines and select gate lines, a pre-programming method that decouples these programming operations can be used. In some implementations, instead of using a single controller or control module that jointly control of pre-programming operations of word lines and select gate lines, the described non-uniform or tailored pre-programming scheme can be achieved by employing different controllers or control modules to separately control the pre-programming of word lines and select gate lines, respectively. The separate control allows for tailored configuration of the pre-programming parameters, e.g., voltage, duration, and rate, specifically for word lines and for select gate lines independently. The described techniques can enable a more precise adjustment of pre-programming outcomes, effectively minimizing the discrepancies in the effects of pre-programming between select gates and word lines across various plane configurations. Consequently, the described techniques can offer a refined mechanism to mitigate the diverse voltage shift patterns associated with word lines and select gate lines, thereby enhancing the control over margin loss attributable to erase interruptions. In some implementations, the described techniques may result in an extension of the erase duration, and can improve the reliability and performance of the memory device by ensuring more consistent erasure and programming characteristics.

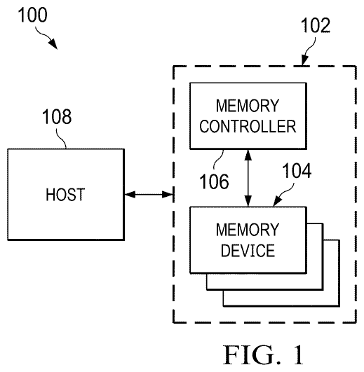

FIG. 1 shows a block diagram of an example system 100, in accordance with some aspects of the present disclosure. System 100 can be a mobile phone, desktop computer, laptop computer, tablet computer, vehicle computer, game console, printer, positioning device, wearable electronic device, smart sensor, Virtual Reality (VR) device, Augmented Reality (AR) device, or any other suitable electronic device having storage therein. As shown in FIG. 1, system 100 can include a host 108 and a memory system 102. Memory system 102 includes one or more memory devices 104 and a memory controller 106. Host 108 can be, for example, a processor (e.g., a Central Processing Unit (CPU)) or a system on a chip (SoC) (e.g., an Application Processor (AP)) of an electronic device. Host 108 can be configured to send data to memory device 104 or receive data from memory device 104. To send data to memory device 104 or receive data from memory device 104, host 108 can send instructions to memory system 102 in addition to the data.

Memory device 104 can be any memory device disclosed in the present disclosure. In some implementations, memory device 104, such as a NAND Flash memory device, can perform a program operation on one or more memory cells such as xLCs (i.e., memory cells configured to store a piece of N-bits data at one of 2^{N} levels, where N is an integer greater than 1) based on a data page having N bits of data for each xLC. In some examples, the xLC may store two bits per cell (MLC), three bits per cell (TLC), or four bits per cell (QLC)).

In some implementations, memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment SSDs or embedded multi-media-cards (cMMCs) used as data storage for mobile devices, such as smartphones, tablets, laptop computers, enterprise storage arrays, and the like.

Memory controller 106 can be configured to control the operation (e.g., read, erase, and program (or write) operations) of memory device 104. For example, based on instructions received from host 108, memory controller 106 can transmit various commands (e.g., program (or write) commands, read commands, erase commands, etc.) to memory device 104 to control the operation of memory device 104. In some implementations, memory controller 106 transmits a program command to memory device 104 to initiate a program operation to be performed by memory device 104. During an ongoing program operation, an interrupt (e.g., a read operation to another page) may occur, for example, from host 108. Memory controller 106 may be configured to transmit an interrupt command to memory device 104 to suspend the program operation. In some implementations, upon completion of other operations triggered by the interrupt, memory controller 106 also can be configured to transmit a resume command to memory device 104 to resume and complete the suspended program operation.

Memory controller 106 can also be configured to manage various functions with respect to data stored or to be stored in memory devices 104, including but not limited to bad block management, garbage collection, logical to physical address translation, wear leveling, and the like. In some implementations, memory controller 106 is also configured to process Error Correction Codes (ECC) with respect to data read from memory device 104 or written to the memory device 104. Memory controller 106 can also perform any other suitable functions, such as formatting memory device 104. The memory controller 106 can communicate with external devices (e.g., host 108) according to a particular communication protocol. For example, the memory controller 106 can communicate with the external device via at least one of various interface protocols, such as a USB protocol, an MMC protocol, a Peripheral Component Interconnect (PCI) protocol, a PCI express (PCI-E) protocol, an Advanced Technology Attachment (ATA) protocol, a serial ATA protocol, a parallel ATA protocol, a small computer system small interface (SCSI) protocol, an Enhanced Small Disk Interface (ESDI) protocol, an Integrated Drive Electronics (IDE) protocol, a Firewire protocol, and so forth.

Memory controller 106 and the one or more memory devices 104 can be integrated into various types of storage devices and can be included, for example, in the same package (e.g., a Universal Flash Storage (UFS) package or an eMMC package). That is, memory system 102 can be implemented and packaged into different types of end electronic products.

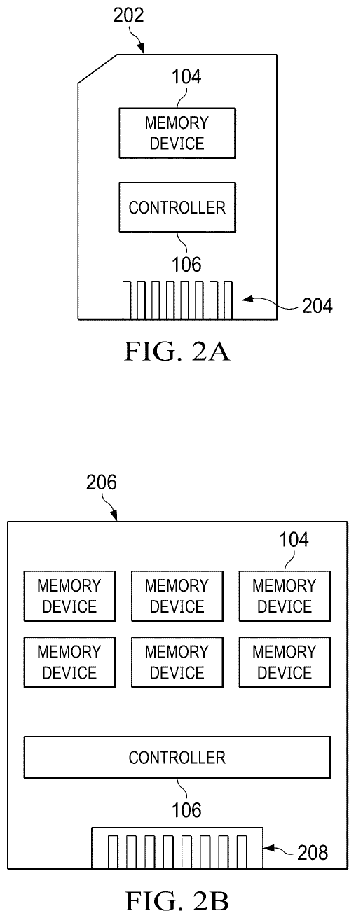

In one example as shown in FIG. 2A, memory controller 106 and the single memory device 104 can be integrated into a memory card 202. Memory card 202 can include a PC card (PCMCIA), a CF card, a Smart Media (SM) card, a memory stick, a multimedia card (MMC, RS-MMC, MMCmicro), an SD card (SD, miniSD, microSD, SDHC), a UFS, and the like. Memory card 202 can also include a memory card connector 204 configured to couple memory card 202 to a host (e.g., host 108 in FIG. 1).

In another example as shown in FIG. 2B, memory controller 106 and multiple memory devices 104 can be integrated into the SSD 206. SSD 206 can also include an SSD connector 208 configured to couple SSD 206 to a host (e.g., host 108 in FIG. 1). In some implementations, the storage capacity and/or operating speed of SSD 206 is greater than the respective storage capacity and/or operating speed of memory card 202.

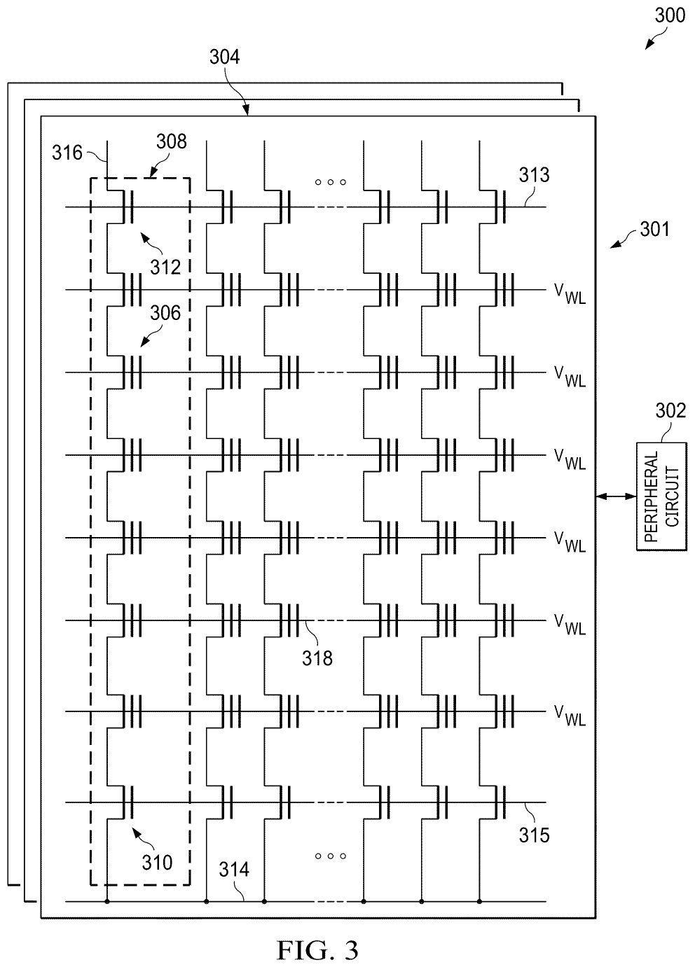

FIG. 3 shows a schematic circuit diagram of a memory device 300 including peripheral circuits, according to some aspects of the present disclosure. Memory device 300 can be an example of memory device 104 in FIG. 1. Memory device 300 can include a memory cell array 301 and peripheral circuits 302 coupled to memory cell array 301. Memory cell array 301 can be a NAND Flash memory cell array in which memory cells 306 are provided in the form of an array of NAND memory strings 308 each extending vertically above a substrate (not shown). In some implementations, each NAND memory string 308 includes a plurality of memory cells 306 coupled in series and stacked vertically. Each memory cell 306 can hold a continuous, analog value, such as an electrical voltage or charge, that depends on the number of electrons trapped within a region of memory cell 306. Each memory cell 306 can be either a floating gate type of memory cell including a floating-gate transistor or a charge trap type of memory cell including a charge-trap transistor.

In some implementations, each memory cell 306 is a single level cell (SLC) that has two possible memory states (levels) and thus, can store one bit of data. For example, the first memory state “0” can correspond to a first range of threshold voltages, and the second memory state “1” can correspond to a second range of threshold voltages. In some implementations, each memory cell 306 is an xLC that is capable of storing more than a single bit of data in more than four memory states (levels). For example, the xLC may store two bits per cell (MLC), three bits per cell (TLC), or four bits per cell (QLC)). Each xLC can be programmed to assume a range of possible nominal storage values (i.e., 2 pieces of N-bits data, e.g., gray codes). In one example, the MLC can be programmed to assume one of three possible programming levels by writing one of three possible nominal storage values to the cell. A fourth nominal storage value can be used for the erased state.

As shown in FIG. 3, each NAND memory string 308 can also include a source select gate (SSG) transistor 310 at its source end and a drain select gate (DSG) transistor 312 at its drain end. SSG transistor 310 and DSG transistor 312 can be configured to activate select NAND memory strings 308 (columns of the array) during read and program operations. In some implementations, the sources of NAND memory strings 308 in the same block 304 are coupled through a same source line (SL) 314, e.g., a common SL. In other words, all NAND memory strings 308 in the same block 304 have an array common source (ACS), according to some implementations. The drain of each NAND memory string 308 is coupled to a respective bit line 316 from which data can be read or written via an output bus (not shown), according to some implementations. In some implementations, each NAND memory string 308 is configured to be selected or deselected by applying a select voltage or a deselect voltage to the gate of respective DSG transistor 312 through one or more DSG lines 313 and/or by applying a select voltage or a deselect voltage to the gate of respective SSG transistor 310 through one or more SSG lines 315.

As shown in FIG. 3, NAND memory strings 308 can be organized into multiple blocks 304, each of which can have a common source line 314, e.g., coupled to the ACS. In some implementations, each block 304 is the basic data unit for erase operations, i.e., all memory cells 306 on the same block 304 are erased at the same time. To erase memory cells 306 in a select block 304, source lines 314 coupled to select block 304 as well as unselect blocks 304 in the same plane as select block 304 can be biased with an erase voltage (Vers), such as a high positive bias voltage (e.g., 20 V or more). Memory cells 306 of adjacent NAND memory strings 308 can be coupled through word lines 318 that select which row of memory cells 306 is affected by read and program operations.

As shown in FIG. 3, memory cell array 301 can include an array of memory cells 306 in a plurality of rows and a plurality of columns in each block 304. One row of memory cells 306 corresponds to one or more pages, and one column of memory cells corresponds to one NAND memory string 308, according to some implementations. The plurality of rows of memory cells 306 can be respectively coupled to word lines 318, and the plurality of columns of memory cells 306 can be respectively coupled to bit lines 316. Peripheral circuit 302 can be coupled to memory cell array 301 through bit lines 316 and word lines 318.

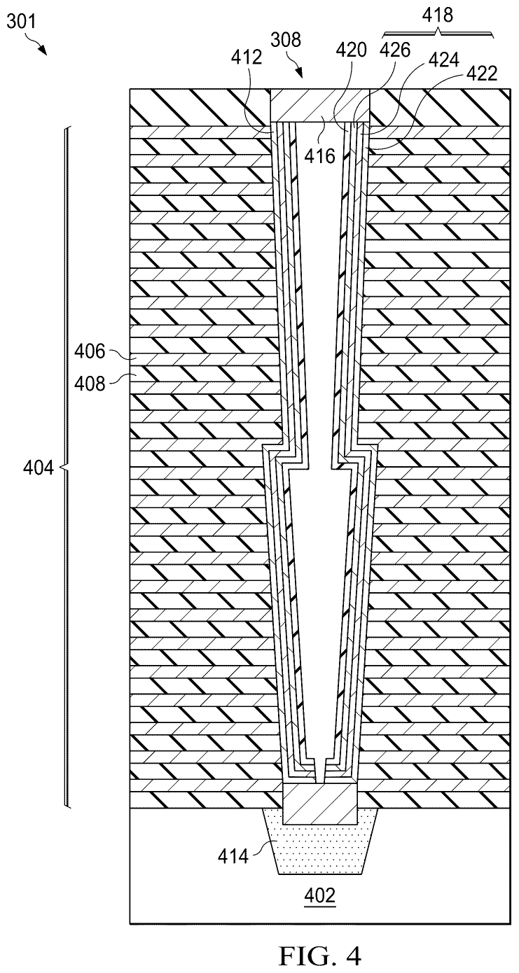

FIG. 4 illustrates a side view of a cross-section of memory cell array 301 including NAND memory string 308, according to some aspects of the present disclosure. As shown in FIG. 4, NAND memory string 308 can extend vertically through a memory stack 404 above a substrate 402. Substrate 402 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 404 can include interleaved gate conductive layers 406 and gate-to-gate dielectric layers 408. The number of the pairs of gate conductive layers 406 and gate-to-gate dielectric layers 408 in memory stack 404 can determine the number of memory cells 306 in memory cell array 301. Gate conductive layer 406 can include conductive materials including, but not limited to, tungsten (W), cobalt (Co), copper (Cu), aluminum (Al), polysilicon, doped silicon, silicides, or any combination thereof. In some implementations, each gate conductive layer 406 includes a metal layer, such as a tungsten layer. In some implementations, each gate conductive layer 406 includes a doped polysilicon layer. Each gate conductive layer 406 can include control gates surrounding memory cells 306, the gates of DSG transistors 312, or the gates of SSG transistors 310, and can extend laterally as DSG line 313 at the top of memory stack 404, SSG line 315 at the bottom of memory stack 404, or word line 318 between DSG line 313 and SSG line 315.

As shown in FIG. 4, NAND memory string 308 includes a channel structure 412 extending vertically through memory stack 404. In some implementations, channel structure 412 includes a channel hole filled with semiconductor material(s) (e.g., as a semiconductor channel 420) and dielectric material(s) (e.g., as a memory film 418). In some implementations, semiconductor channel 420 includes silicon, such as polysilicon. In some implementations, memory film 418 is a composite dielectric layer including a tunneling layer 426, a storage layer 424 (also known as a “charge trap/storage layer”), and a blocking layer 422. Channel structure 412 can have a cylinder shape (e.g., a pillar shape). Semiconductor channel 420, tunneling layer 426, storage layer 424, blocking layer 422 are arranged radially from the center toward the outer surface of the pillar in this order, according to some implementations. Tunneling layer 426 can include silicon oxide, silicon oxynitride, or any combination thereof. Storage layer 424 can include silicon nitride, silicon oxynitride, silicon, or any combination thereof. Blocking layer 422 can include silicon oxide, silicon oxynitride, high dielectric constant (high-k) dielectrics, or any combination thereof. In one example, memory film 418 may include a composite layer of silicon oxide/silicon oxynitride/silicon oxide (ONO).

As shown in FIG. 4, a well 414 (e.g., a P-well and/or an N-well) is formed in substrate 402, and the source end of NAND memory string 308 is in contact with well 414, according to some implementations. For example, source line 314 may be coupled to well 414 to apply an erase voltage to well 414, i.e., the source of NAND memory string 308, during erase operations. In some implementations, NAND memory string 308 further includes a channel plug 416 at the drain end of NAND memory string 308. It is understood that although not shown in FIG. 4, additional components of memory cell array 301 can be formed including, but not limited to, gate line slits/source contacts, local contacts, interconnect layers, etc.

As shown in FIG. 4, memory stack 404 includes two sections or groups of cells within the stack, namely, upper deck 440 and lower deck 440. In the context of 3D memory devices, memory cells are stacked vertically in multiple layers to increase storage density. A “deck” in this context is a subset of these layers. For example, if a memory string has 64 layers, it might be divided into an upper and a lower deck, each comprising 32 layers. The division into decks is not just physical but also functional. Each deck can be independently accessed and operated, which can improve performance, reduce power consumption, and increase the efficiency of memory operations. In the shown example, lower deck 440 refers to the layers closer to the substrate 402, and upper deck 430 refers to the layers further away from the substrate 402. By organizing the memory cells into decks, it can reduce interference between cells, which can improve data integrity and read/write speeds. Different decks can be used to implement wear-leveling strategies, distributing write and erase cycles across the memory chip to prolong its lifespan. This architecture also allows for scalability in memory design. For example, manufacturers can increase storage capacity by adding more layers (i.e., decks) without significantly increasing the chip's footprint.

In some cases, variations in the size of the channel structure along the vertical direction, e.g., the stacking direction of the memory cells, in the decks of a memory string in 3D memory devices can occur due to several factors inherent in the manufacturing process. For example, the variations in the size of the channel structure can occur due to one or more of the following factors: deposition inconsistencies, etching variabilities, lithography challenges, stress and strain during fabrication, chemical mechanical polishing (CMP) irregularities, thermal effects, diffusion and material interactions, or limitations of current technology.

In the shown example, channel structure 412 within each deck of upper deck 430 and lower deck 440 exhibits a dimensional decrement proceeding from the topmost layer towards the bottommost layer. This gradation is manifested as a progressive reduction in the cross-sectional area of channel structure 412, whereby the uppermost layer of each deck possesses the largest channel size, and this channel size diminishes in each subsequent layer down to the lowermost layer of the deck.

Note that memory string 308 in FIG. 4 is shown to include two decks for illustrative purposes. In some examples, memory string 308 can have any suitable number of decks, where each deck can have any suitable number of layers, such as 4 decks each consisting of 8 layers, 8 decks each consisting of 8 layers or 12 layers, 16 decks each consisting of 8 layers, or 22 decks each consisting of 8 layers.

Referring back to FIG. 3, peripheral circuits 302 can be coupled to memory cell array 301 through bit lines 316, word lines 318, source lines 314, SSG lines 315, and DSG lines 313. Peripheral circuits 302 can include any suitable analog, digital, and mixed-signal circuits for facilitating the operations of memory cell array 301 by applying and sensing voltage signals and/or current signals to and from each select memory cell 306 through bit lines 316, word lines 318, source lines 314, SSG lines 315, and DSG lines 313. Peripheral circuits 302 can include various types of peripheral circuits formed using metal-oxide-semiconductor (MOS) technologies.

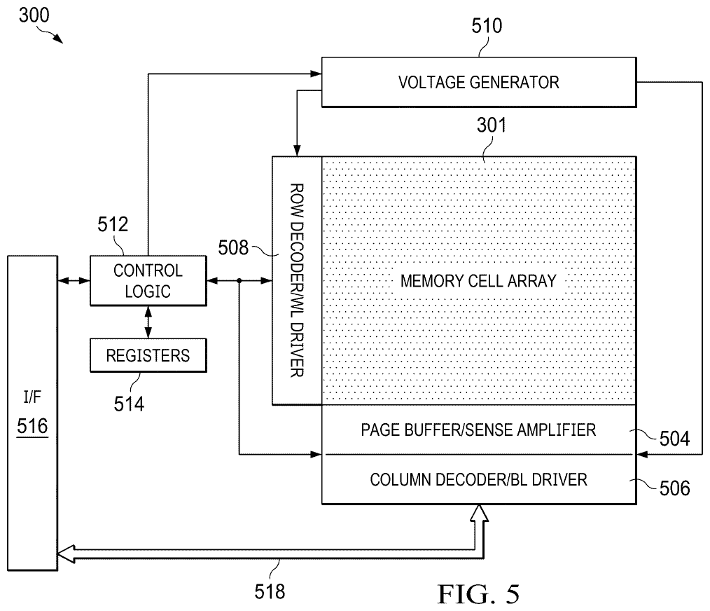

FIG. 5 illustrates some exemplary peripheral circuits including a page buffer/sense amplifier 504, a column decoder/bit line driver 506, a row decoder/word line driver 508, a voltage generator 510, control logic 512, registers 514, an interface 516, and a data bus 518. It is understood that, in some examples, additional peripheral circuits not shown in FIG. 5 may be included as well.

Page buffer/sense amplifier 504 can be configured to read and program (write) data from and to memory cell array 301 according to the control signals from control logic 512. In one example, page buffer/sense amplifier 504 may store data to be programmed into one page of memory cell array 301. In another example, page buffer/sense amplifier 504 may verify programmed select memory cells 306 in each program/verify loop (cycle) in a program operation to ensure that the data has been properly programmed into memory cells 306 coupled to select word lines 318. In still another example, page buffer/sense amplifier 504 may also sense the low power signals from bit line 316 that represents a data bit stored in memory cell 306 and amplify the small voltage swing to recognizable logic levels in a read operation. As described below in detail and consistent with the scope of the present disclosure, in program operations, page buffer/sense amplifier 504 can include a plurality of page buffer circuits respectively coupled to bit lines 316, and each including a set of storage units (e.g., latches) for temporarily storing a piece of N-bits data (e.g., in the form of gray codes) received from data bus 518 and providing the piece of N-bits data to a corresponding select memory cell 306 through the corresponding bit line 316 in a program operation using a multi-cache loading scheme.

Column decoder/bit line driver 506 can be configured to be controlled by control logic 512 and select one or more NAND memory strings 308 by applying bit line voltages generated from voltage generator 510. Row decoder/word line driver 508 can be configured to be controlled by control logic 512 and select/deselect blocks 304 of memory cell array 301 and select/deselect word lines 318 of block 304. Row decoder/word line driver 508 can be further configured to drive word lines 318 using word line voltages generated from voltage generator 510. In some implementations, row decoder/word line driver 508 can also select/deselect and drive SSG lines 315 and DSG lines 313 as well. Voltage generator 510 can be configured to be controlled by control logic 512 and generate the word line voltages (e.g., read voltage, program voltage, channel pass voltage, local voltage, verify voltage, etc.), bit line voltages, and source line voltages to be supplied to memory cell array 301.

Control logic 512 can be coupled to each peripheral circuit described above and configured to control the operations of each peripheral circuit. Registers 514 can be coupled to control logic 512 and include status registers, command registers, and address registers for storing status information, command operation codes (OP codes), and command addresses for controlling the operations of each peripheral circuit. Interface 516 can be coupled to control logic 512 and act as a control buffer to buffer and relay control commands received from a memory controller (e.g., 106 in FIG. 1) and/or a host (e.g., 108 in FIG. 1) to control logic 512 and status information received from control logic 512 to the memory controller and/or the host. Interface 516 can also be coupled to column decoder/bit line driver 506 via data bus 518 and act as a data input/output (I/O) interface and a data buffer to buffer and relay the data to and from memory cell array 301.

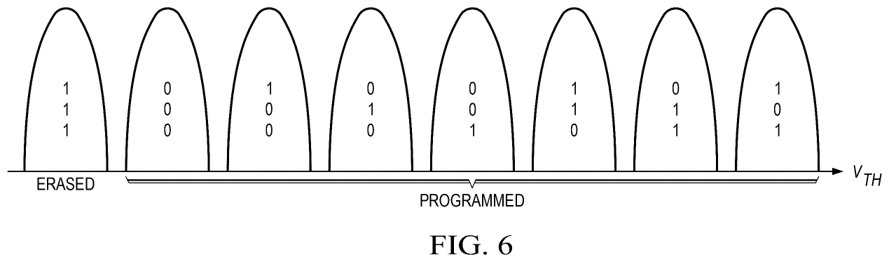

FIG. 6 illustrates exemplary threshold voltage distributions of memory cells in a program operation, according to some aspects of the present disclosure. As described above, each memory cell 306 can be configured to store a piece of N-bits data in one of 2^{N} levels, where N is an integer greater than 1 (e.g., N=2 for MLCs, N=3 for TLCs, N=4 for QLCs, etc.). Each level can correspond to one of 2^{N} threshold voltage (VTH) ranges of memory cells 306. Taking TLCs, where N=3, for example, as shown in FIG. 6, memory cell 306 may be programmed into one of the 8 levels, including one level of the erased state and 7 levels of the programmed states. Each level may correspond to a respective threshold voltage (VTH) range of memory cells 306. For example, the level corresponding to the lowest threshold voltage range (the left-most threshold voltage distribution in FIG. 6) may be considered as level 0, the level corresponding to the second-lowest threshold voltage range (the second left-most threshold voltage distribution in FIG. 6) may be considered as level 1, and so until level 7 corresponding to the highest threshold voltage range (the right-most threshold voltage distribution in FIG. 6).

Each level can correspond to one of the 2^{N} pieces of N-bits data that is to be stored in a selected memory cell 306. In some implementations, the 2^{N} pieces of N-bits data may be represented by (in the form of) a gray code. A gray code (a.k.a., reflected binary code (RBC) or reflected binary (RB)) is an ordering of the binary numeral system such that two successive values differ in only one bit (binary digit). For example, TABLE 1 below shows an example of a binary code representing a one-to-one mapping between 8 levels (LV 0 to LV 7) and 8 pieces of 3-bits data used in the example of FIG. 6. As shown in TABLE 1, each piece of 3-bits data may consist of three bits of binary values (b1, b2, and b3). In one example, level 1 may correspond to a piece of 3-bits data having a value of 000. In another example, level 7 may correspond to another piece of 3-bits data having a value of 101.

TABLE 1

| LV | 0 | 1 | 2 | 3 | 4 | 5 | 6 | 7 |
|---|---|---|---|---|---|---|---|---|
| b1 | 1 | 0 | 1 | 0 | 0 | 1 | 0 | 1 |
| b2 | 1 | 0 | 0 | 1 | 0 | 1 | 1 | 0 |
| b3 | 1 | 0 | 0 | 0 | 1 | 0 | 1 | 1 |

Also referring to FIG. 5, in a program operation, user data can be used to program a selected row of memory cells 306 coupled to select word line 318. In some implementations, user data is transmitted through data bus 518 to page buffer/sense amplifier 504, and page buffer/sense amplifier 504 is configured to convert the user data into data to be programmed into a respective row of memory cells 306 based on a preset gray code. Based on the preset gray code, which defines the mapping of each programmed level and a respective piece of N-bits data, control logic 512 is configured to send control signals (e.g., enable signals) to page buffer/sense amplifier 504 to allow page buffer/sense amplifier 504 to generate data for sequential program operations, according to some implementations. During the ongoing program operation, the current data can be temporarily stored in page buffer/sense amplifier 504, and page buffer/sense amplifier 504 can be configured to provide to each memory cell 306 coupled to select word line 318 the corresponding data through the corresponding bit line 316.

To perform a program operation, in addition to page buffer/sense amplifier 504 providing to each select memory cell 306 the corresponding data, row decoder/word line driver 508 can be configured to apply program voltages and verify voltages to a select word line 318 coupled to a select row of memory cells 306 in one or more program/verify loops in order to raise the threshold voltage of each select memory cell 306 to a desired level (into a desired range of threshold voltages) based on the corresponding data.

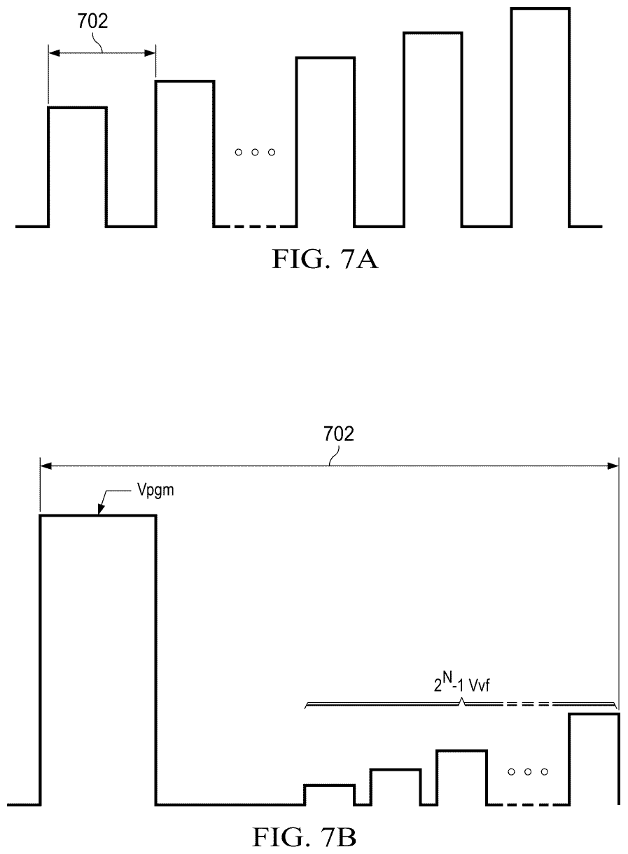

FIGS. 7A and 7B illustrate a waveform of word line voltages applied to a word line in a program operation, according to some implementations of the present disclosure. As shown in FIG. 7A, the program operation includes one or more program/verify loops (cycles) 702. As shown in FIG. 7B, in each program/verify loop 702, row decoder/word line driver 508 can be configured to apply a program voltage (V_{pgm}) on a word line (e.g., word line 318) and apply one or more (e.g., up to 2^{N}−1) verify voltages (V_{vf}) to verify whether a target memory cell has been properly programmed into a target programmed level. The 2^{N}−1 verify voltages can correspond to 2^{N}−1 levels of the 2^{N} levels (e.g., the 2^{N}−1 programmed levels). That is, peripheral circuit 302 can be configured to verify the select row of memory cells 306 at the 2^{N}−1 levels of the 2^{N} levels. Each select memory cell 306 can be programmed into one of the 2^{N}−1 levels based on the corresponding data to be stored in select memory cell 306, i.e., the current data stored in the corresponding page buffer circuit 702. Still taking TLCs where N=3 as an example, select memory cells 306 may be sequentially programmed into one of 7 programmed levels (e.g., shown in FIG. 6). 7 verify voltages each corresponding to one of the 7 programmed levels can be applied to verify whether a memory cell has been programmed into a target programmed level.

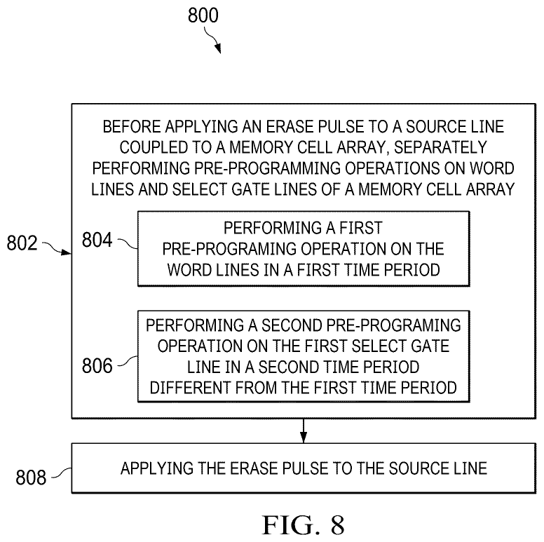

FIG. 8 illustrates an example process 800 of performing an erase operation in a memory device, according to some implementations of the present disclosure. Process 800 can be performed by any suitable device as described herein, such as memory device 104, memory device 106, or memory device 300. The operations shown in process 800 may not be exhaustive and that other operations can be performed as well before, after, or in between any of the illustrated operations. Further, some of the operations may be performed simultaneously, or in a different order than shown in FIG. 8.

In some implementations, the erase operation can include a pre-programming operation performed before applying an erase pulse, for example, to compensate for voltage shifts caused by the erase pulse. In process 800, a memory device, e.g., memory device 300, separately performs pre-programming operations on word lines and select gate lines of a memory cell array in the memory device (802). In some implementations, the memory device performs the pre-programming operations prior to applying an erase pulse to a source line coupled to the memory cell array. In some examples, the memory device includes a memory cell array and a peripheral circuit coupled to the memory cell array. The peripheral circuit can be configured to control the pre-programming operations.

In some implementations, the erase operation can be a GIDL erase operation, and the erase pulse is an erase pulse of a GIDL erase operation.

In some examples, a pre-programming operation can include applying a specific voltage to the control gates of the memory cells, causing the memory cells to store a charge in their floating gates. This process effectively programs all the memory cells to a same or similar threshold voltage level. After pre-programming, the memory cells can all start the erase process from the same or similar threshold voltage level. This uniformity helps mitigate the issue of some cells being over-erased or under-erased compared to others, which can occur due to the inherent variability in the GIDL erase process.

In some cases, transistors in different sections of a memory array can experience different levels of threshold voltage shifts. For example, select gates coupled to select gate lines and memory cells coupled to word lines can experience different levels of voltage shifts. To compensate for the varying levels of voltage shifts experienced by different sections of a memory array, a non-uniform pre-programming scheme can be used. For example, different pre-programming operations can be performed on different sections of the memory array during different time periods.

In some implementations, the select gate lines include a first select gate line. In such implementations, the memory device performs the non-uniform pre-programming operations by performing a first pre-programing operation on the word lines in a first time period (804), and performing a second pre-programing operation on the first select gate line in a second time period different from the first time period (806).

In some implementations, a starting time point of the second time period is prior to a starting time point of the first time period. In some implementations, a starting time point of the first time period is prior to a starting time point of the second time period.

In some implementations, the first time period and the second time period do not overlap. For example, a starting time point of the second time period can be later than an ending time point of the first time period. The non-overlapping pre-programing operations can occur, for example, in scenarios where the first pre-programing operation and the second pre-programing operation share the same voltage source.

In some implementations, the first time period and the second time period overlap partially. For example, a starting time point of the second time period can be later than a starting time point of the first time period but earlier than an ending time point of the first time period. In some examples, when distinct pre-programming operations are applied to word lines and select gate lines, there can be partial overlapping in the pre-programming phases of these components. For example, when a voltage source supplying a programming voltage is utilized for the pre-programming of word lines and another voltage source supplying a pass voltage to the select gate lines, the first time period and the second time period can overlap partially. The utilization of different voltage sources can enable the concurrent adjustment of pre-programming parameters for each component, thereby allowing for a simultaneous yet differentiated pre-programming process.

In some implementations, performing the first pre-programing operation on the word lines in the first time period includes applying a first voltage to the word lines in the first time period, and applying a second voltage to the first select gate line in the first time period. In such implementations, the first voltage is higher than the second voltage. In some examples, the first voltage can be a program voltage, which is a specific voltage level applied to the word lines to alter the state of (i.e., program) the memory cells coupled by the word lines, and the second voltage can be a pass voltage, which is a specific voltage level applied to the select gate lines to prevent the select gates coupled by the select gate lines from being inadvertently interfered by other memory cells or select gates. In some examples, a voltage level of the first voltage is in a range of 11-25 volts, and a voltage level of the second voltage is in a range of 3-11 volts.

In some implementations, performing the second pre-programing operation on the first select gate line in the second time period includes applying a third voltage to the first select gate line in the second time period, and applying a fourth voltage to the word lines in the second time period, wherein the third voltage is higher than the fourth voltage. In some examples, the third voltage can be a program voltage, and the fourth voltage can be a pass voltage. In some examples, a voltage level of the third voltage is in a range of 11-25 volts, and a voltage level of the fourth voltage is in a range of 3-11 volts.

In some implementations, a voltage level of the first voltage is the same as a voltage level of the third voltage, and a voltage level of the second voltage is the same as a voltage level of the fourth voltage.

In some implementations, a voltage level of the third voltage is higher than a voltage level of the first voltage. For example, word lines, which control data access in memory cells, can require lower voltages than the ones applied to the select gates. Preprogramming the word line can elevate the memory cell from a lower state to a higher state, reducing the risk of excessive erasure. Although this process may modify the stored data, the subsequent erasure operation can ensure that these changes do not have lasting effects. Given that the word line is scheduled for erasure, the voltage of the preprogramming can be relatively lower than those of the select gates. Select gates, responsible for isolating memory sections during operations like erasing or programming, may require higher voltages for effective isolation.

By employing different pre-programming strategies to different transistors in different sections of a memory array, it is possible to normalize the conditions across the memory array, leading to more uniform and predictable performance of all memory cells. Customized pre-programming for the word lines and the select gates allows for adjusting the starting threshold voltages of the memory cells, ensuring that the memory cells are within a desired operational range, for example, for subsequent erase operations.

In some implementations, the select gate lines include one or more select gate lines in addition to the first select gate line. The select gate lines can be in different layers or planes. The pre-programming operation on the word lines is performed separately from the pre-programming operation on the select gate lines. In some implementations, the pre-programming operation on the select gate lines are preformed separately too, for example, based on the layers or planes that the select gate lines are in.

In some implementations, the select gate lines further include a second select gate line. In such implementation, separately performing the pre-programming operations on the word lines and the select gate lines includes performing the first pre-programming operation on the word lines in a first time period, performing the second pre-programming operation on the first select line in a second time period, and performing the third pre-programming operation on the second select line in a third period, where the third time period is different from the first time period. In some implementations, the third time period is different from both the first time period and the second time period.

In some implementations, there is no strict order of performing the first pre-programming operation on the word lines, performing the second pre-programming operation on the first select line, and performing the third pre-programming operation on the second select line. For example, the three pre-programming operations can be performed in any order.

In some implementations, the first select gate line and the second select gate line are bottom select gate (BSG) lines. In some implementations, one of the first select gate line and the second select gate line is a BSG line, and the other one is a top select gate (TSG) line.

In some implementations, the durations of two or more of the time periods can be the same or different. In some implementations, the voltages applied to the word lines and respective select gate lines can be different. In some implementations, the durations of the time periods and the voltages used in the time periods can be designed, determined or otherwise configured based on one or more loading of the word lines, locations of the word lines relative to the select gate lines, and other factors that may cause the voltage shifts.

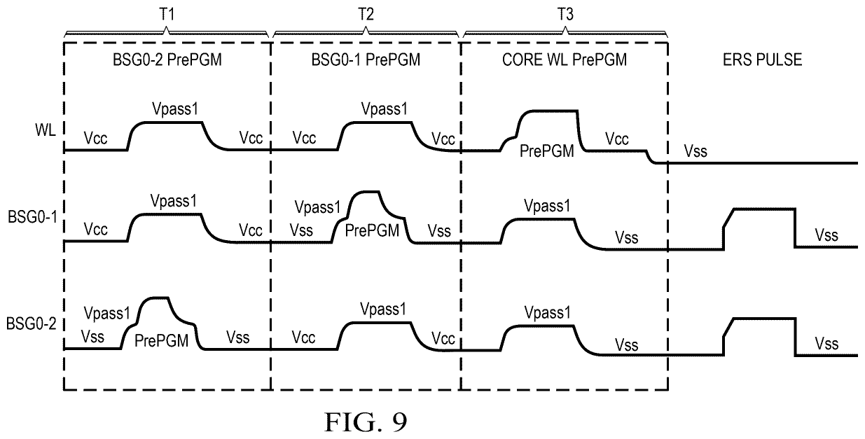

FIG. 9 illustrates a diagram showing an example process of performing pre-programming operations on word lines and select gate lines in an example memory device, in accordance with one or more implementations of the present disclosure. The example memory device includes at least two layers of BSG, BSG0-1 and BSG0-2. In the shown example of FIG. 9, different pre-programming operations are applied to word lines, WL, and select gates, BSG0-1 and BSG0-2, in different time periods. In the shown example, in a first time period “T1”, a pre-programming operation is performed on a second select gate line, BSG0-2. During T1, a pass voltage is applied to word lines, WL, and a first BSG line, BSG0-1, and a program voltage is applied to the second BSG line, BSG0-2. In a second time period “T2”, a pre-programming operation is performed on a first select gate line, BSG0-1. During T2, a pass voltage is applied to the word lines, WL, and the second BSG line, BSG0-2, and a program voltage is applied to the first BSG line, BSG0-1. In a third time period “T3”, a pre-programming operation is performed on the word lines, WL. During T3, a program voltage is applied to the word lines, WL, and a pass voltage is applied to the first BSG, BSG0-1, and the second BSG, BSG0-2. In the shown example of FIG. 9, the three time periods, T1, T2, and T3 do not overlap. In some other cases, the three time periods may partially overlap. In some implementations, the durations of the three time periods can be the same, while in some other implementations, the durations of the three time periods can be different.

The non-uniform pre-programming scheme can be beneficial especially when different select gates experience varying threshold voltage shifts. For example, different select gates may experience varying levels of threshold voltage shift due to GIDL erase. This variability can be caused by differences in physical layout, manufacturing inconsistencies, or varying local electrical environments within the memory array. The ramp step, or the manner in which the voltage is increased during programming or erase operations, can also affect how GIDL influences the select gates. A slower or more gradual ramp step might lead to different GIDL effects compared to a rapid voltage change. This is because the rate of voltage change can impact the amount of charge accumulation and the resulting stress on the gate oxide. Moreover, each select gate might be subject to different localized conditions, such as temperature variations, differing levels of electrical interference, or stress from adjacent cells. These conditions can alter the way each gate responds to the same erase or programming voltage. To counter these variations, applying different pre-programming operations to the select gates allows for a more tailored approach to maintaining consistent performance and reliability in semiconductor memory devices.

After the pre-programming operations, a normal erase operation can be carried out, for example, by applying an erase pulse to a source line. Since the cells are starting from a uniform state, the erase operation can be more controlled and predictable, leading to a more uniform threshold voltage across the memory array after erasure.

Referring back to FIG. 8, after performing the pre-programing operations on the word lines and the select gates, the memory device applies the erase pulse to the source line (808).

In some examples, applying an erase pulse to a source line can include identifying the block or blocks of memory cells that need to be erased, isolating the target block from the rest of the memory array by applying appropriate voltages to the select gates, holding all the word lines in the block at a low voltage (e.g., ground potential), and applying a high voltage to the source line.

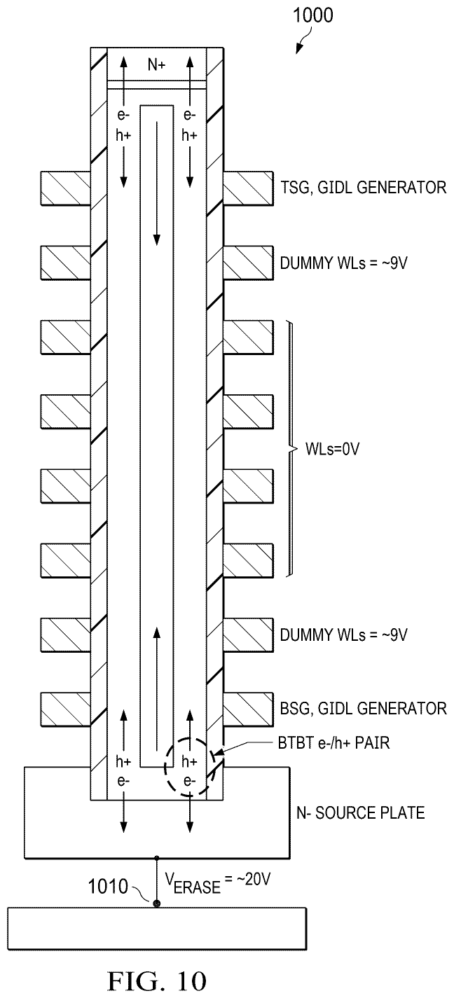

FIG. 10 illustrates an example of applying an erase pulse to a block of memory cells in a memory cell array, in accordance with one or more implementations of the present disclosure. As shown in FIG. 10, an erase pulse having a voltage level of approximately 20 volts is applied to source line 1010 coupled to memory block 1000.

In some implementations, the duration of the erase pulse is long enough to ensure that all cells in the block are sufficiently erased, but not so long that it causes over-erasing or stresses the memory cells, which can reduce their lifespan. In some examples, the duration of the erase pulse can be determined based on manufacturer specifications, material properties, device characteristics, adaptive algorithms, and safety considerations.

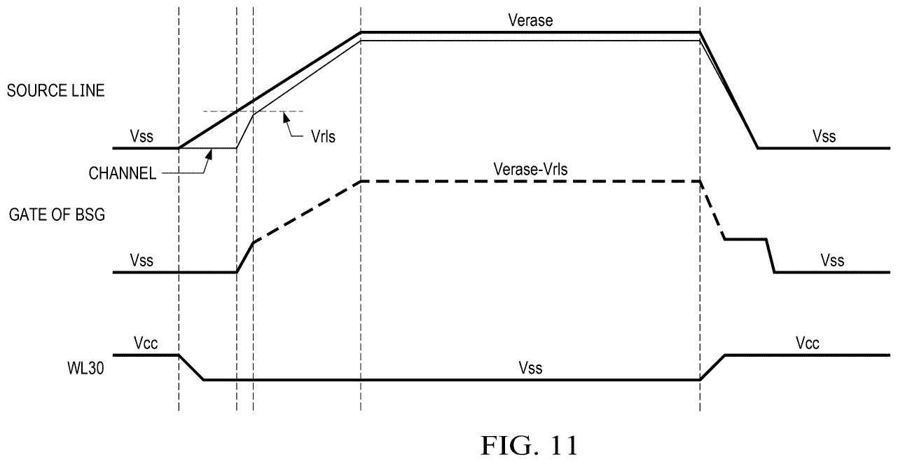

In some implementations, when applying the erase pulse to the source line, the memory device maintains a voltage of the select gate lines at an initial voltage, e.g., a ground potential, in an initial phase of the erase pulse. In such implementations, a voltage of the erase pulse progressively increases over time in the initial phase. When the erase pulse reaches a threshold, the memory device allows the voltage of the select gate lines to increase, for example, by floating the select gate lines or setting gates of the select gate lines to float. For example, referring to FIG. 11, an erase pulse applied to the source line starts at a low voltage “Vₛₛ”, such as ground potential, then rises progressively to a high voltage “Vₑᵣₐₛₑ”. The erase pulse continues to stay at the high voltage “Vₑᵣₐₛₑ” for a predetermined time period, then drops to the low voltage “Vₛₛ”. In the shown example, while the erase pulse is applied to the source line, a voltage of the select gate line is maintained initially at a low voltage “Vₛₛ”, such as ground potential. When the erase pulse reaches a predetermined threshold “Vᵣₗₛ.” the gate of the select gate line is set to float and the voltage of the select gate line starts to rise. When the voltage pulse applied to the select gate line reaches a predetermined high voltage, it stays at the predetermined high voltage for a predetermined time period, then drops to the low voltage “Vₛₛ”. In the shown example, the voltage of the word lines is initially held at a high voltage “V_{cc}”, and starts to drop to the low voltage “Vₛₛ” when the erase pulse applied to the source line starts to rise up from the low voltage “Vₛₛ”.

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents. Accordingly, other implementations also are within the scope of the claims.

What is claimed is:

1. A method for performing an erase operation in a memory device, comprising:
before applying an erase pulse to a source line coupled to a memory cell array of the memory device, separately performing pre-programming operations on word lines and select gate lines of the memory cell array, wherein the select gate lines comprise a first select gate line, and wherein separately performing the pre-programming operations on the word lines and the select gate lines comprises:
performing a first pre-programing operation on the word lines in a first time period; and
performing a second pre-programing operation on the first select gate line in a second time period different from the first time period; and
applying the erase pulse to the source line.

2. The method according to claim 1, wherein the method comprises:
when applying the erase pulse to the source line, maintaining a voltage of the select gate lines at an initial voltage in an initial phase of the erase pulse, wherein a voltage of the erase pulse increases over time in the initial phase; and
in response to determining that the erase pulse reaches a threshold, floating the select gate lines.

3. The method according to claim 1, wherein a starting time point of the second time period is prior to a starting time point of the first time period.

4. The method according to claim 1, wherein performing the first pre-programing operation on the word lines in the first time period comprises:
applying a first voltage to the word lines in the first time period; and
applying a second voltage to the first select gate line in the first time period,
wherein the first voltage is higher than the second voltage.

5. The method according to claim 4, wherein the first voltage is a program voltage, and the second voltage is a pass voltage.

6. The method according to claim 4, wherein a voltage level of the first voltage is in a range of 11-25 volts, and a voltage level of the second voltage is in a range of 3-11 volts.

7. The method according to claim 4, wherein performing the second pre-programing operation on the first select gate line in the second time period comprises:
applying a third voltage to the first select gate line in the second time period; and
applying a fourth voltage to the word lines in the second time period,
wherein the third voltage is higher than the fourth voltage.

8. The method according to claim 7, wherein the third voltage is higher than the first voltage.

9. The method according to claim 1, wherein:
the select gate lines further comprise a second select gate line; and
separately performing the pre-programming operations on the word lines and the select gate lines further comprises:
performing a third pre-programing operation on the second select gate line in a third time period, wherein the third time period is different from the first time period and the second time period.

10. The method according to claim 9, wherein the first select gate line and the second select gate line are bottom select gate (BSG) lines.

11. A memory device, comprising:
a memory cell array; and
a peripheral circuit coupled to the memory cell array, wherein the peripheral circuit is configured to:
before applying an erase pulse to a source line coupled to the memory cell array of the memory device, separately perform pre-programming operations on word lines and select gate lines of the memory cell array, wherein the select gate lines comprise a first select gate line, and wherein separately performing the pre-programming operations on the word lines and the select gate lines comprises:
performing a first pre-programing operation on the word lines in a first time period; and
performing a second pre-programing operation on the first select gate line in a second time period different from the first time period; and
apply the erase pulse to the source line.

12. The memory device according to claim 11, wherein the peripheral circuit is configured to:
when applying the erase pulse to the source line, maintain a voltage of the select gate lines at an initial voltage in an initial phase of the erase pulse, wherein a voltage of the erase pulse progressively increases over time in the initial phase; and
in response to determining that the erase pulse reaches a predetermined threshold, start to increase the voltage of the select gate lines.

13. The memory device according to claim 11, wherein a starting time point of the second time period is prior to a starting time point of the first time period.

14. The memory device according to claim 11, wherein performing the first pre-programing operation on the word lines in the first time period comprises:
applying a first voltage to the word lines in the first time period; and
applying a second voltage to the first select gate line in the first time period,
wherein the first voltage is higher than the second voltage.

15. The memory device according to claim 14, wherein the first voltage is a program voltage, and the second voltage is a pass voltage.

16. The memory device according to claim 14, wherein a voltage level of the first voltage is in a range of 11-25 volts, and a voltage level of the second voltage is in a range of 3-11 volts.

17. The memory device according to claim 14, wherein performing the second pre-programing operation on the first select gate line in the second time period comprises:
applying a third voltage to the first select gate line in the second time period; and
applying a fourth voltage to the word lines in the second time period,
wherein the third voltage is higher than the fourth voltage.

18. The memory device according to claim 17, wherein the third voltage is higher than the first voltage.

19. The memory device according to claim 11, wherein:
the select gate lines further comprise a second select gate line; and
separately performing the pre-programming operations on the word lines and the select gate lines further comprises:
performing a third pre-programing operation on the second select gate line in a third time period, wherein the third time period is different from the first time period and the second time period.

20. A system, comprising a memory device and a controller coupled to the memory device, wherein the memory device comprises:
a memory cell array; and
a peripheral circuit coupled to the memory cell array, wherein the peripheral circuit is configured to:
before applying an erase pulse to a source line coupled to the memory cell array of the memory device, separately perform pre-programming operations on word lines and select gate lines of the memory cell array, wherein the select gate lines comprise a first select gate line, and wherein separately performing the pre-programming operations on the word lines and the select gate lines comprises:
performing a first pre-programing operation on the word lines in a first time period; and
performing a second pre-programing operation on the first select gate line in a second time period different from the first time period; and
apply the erase pulse to the source line.
